(19) United States
(12) Patent Application Publication
(10) Pub. No.: US 2026/0333607 A1
(43) Pub. Date: Oct. 22, 2026

(54) CONNECTION ARRANGEMENT COMPRISING A PRINTED CIRCUIT BOARD AND A HOUSING

(71) Applicant: HELLA GMBH & CO. KGAA, Lippstadt (DE)

(72) Inventor: Marcus Gattwinkel, Telgte (DE)

(21) Appl. No.: 19/648,294

(22) Filed: Apr. 15, 2026

(30) Foreign Application Priority Data
Apr. 16, 2025 (DE) 102025114980.1

(51) Int. Cl. H05K 7/14

(52) U.S. Cl. CPC H05K 7/1405; H05K 7/1427

(57) ABSTRACT

The present invention relates to a connection arrangement including a printed circuit board and a housing. The printed circuit board has a board body that is enclosed by the housing at least in sections. According to the invention, the board body has at least one spring tongue that is surrounded by a recess and is latched to a latching nose on the housing to form a snap-fit connection.

### CROSS-REFERENCE TO RELATED APPLICATIONS

This application claims the benefit of German Patent Application 10-2025-114-980.1, filed Apr. 16, 2025, the disclosure of which is incorporated by reference in its entirety.

### FIELD OF THE INVENTION

The present invention relates to a connection arrangement comprising a printed circuit board and an associated housing, wherein the printed circuit board has a board body that is enclosed by the housing at least in sections.

### BACKGROUND OF THE INVENTION

Circuit components of electronic devices are usually arranged on printed circuit boards (PCB), which have a board body as a carrier for the circuit components and their electrical supply lines. The printed circuit boards are structurally integrated into the devices via suitably designed housings that enclose the board body at least in sections. For example, such a housing has a receiving space with a slot-shaped cross-section into which a printed circuit board is inserted.

In applications in which the associated electronic devices are exposed to operational movements, vibrations, or impacts, for example, in electronic devices installed on board a motor vehicle, unwanted rattling noises or the like may occur due to the movements of the printed circuit board in the assembly gap on the housing. Countermeasures known in the prior art include, for example, the use of screw connections, separate cover frames, or potting compounds.

### SUMMARY OF THE INVENTION

It is the object of the present invention to propose an alternative embodiment of a connection arrangement comprising a printed circuit board and a housing, which permits robust fixing of the printed circuit board, in particular in a particularly practical manner, and also requires very little installation space. This object is achieved by a connection arrangement according to embodiments disclosed herein.

The technical teaching of the invention discloses that the board body of the printed circuit board has at least one spring tongue that is surrounded by a recess, which is latched to a latching nose on the housing to form a snap-fit connection.

The invention is based on the idea of integrating a connection means directly into the printed circuit board, namely in the form of a spring tongue that is formed by inserting a suitable board recess into the board body. The spring tongue has an exposed end and a base portion that merges into the rest of the board body. This allows the spring tongue to be deflected out of the plane of the board body with elastic deformation and latched in place with a corresponding rigid latching nose on the housing by resilient expansion. The latched spring tongue bridges the already existing assembly gap between the printed circuit board and the housing so that no additional installation space needs to be provided for the snap-fit connection according to the invention. Furthermore, the snap-fit connection is established automatically when the printed circuit board is inserted into the receiving space in the housing, in that the spring tongue slides along the latching nose during the insertion and is thereby deflected. In particular, the spring tongue has a receiving opening for receiving and securing the latching nose in the latched position. The latching nose may preferably be integrally formed directly on the housing, or the housing is provided with a suitable insert part or the like, which has the latching nose.

In particular, the latched spring tongue is elastically biased so that a frictional connection is formed between bearing portions of the board body and of the housing. In other words, the latched spring tongue presses the printed circuit board against the housing. This is a particularly effective way of securing the printed circuit board in the housing, which suppresses unwanted rattling caused by operational vibrations or impacts.

In an advantageous embodiment, the base portion of the spring tongue has a necked portion such that the bending stress of the latched spring tongue is maximal in the region of the necked portion. Due to this stress concentration in the region of the necked portion, the regions of the board body adjoining the base portion are relieved. This is particularly important in particular in the presence of mechanically sensitive electronic components on the printed circuit board, such as ceramic capacitors, in order to protect them from damage, such as cracking, caused by mechanical stresses originating from the latched spring tongue. Furthermore, the necked portion may also be used to absorb any torsional moments that occur in the snap-fit connection.

Depending on the specific configuration of the printed circuit board and the housing, several snap-fit connections designed according to the invention may also be provided. The board body may, for example, be made of a fiber-reinforced epoxy resin (FR-4 materials) or may have a metal core (IMS types). From a manufacturing perspective, the recess for forming the spring tongue and/or the receiving opening is preferably formed in the board body by milling.

### BRIEF DESCRIPTION OF THE DRAWINGS

The invention is illustrated below by means of exemplary embodiments with reference to the figures and the associated description. In the drawings:

FIG. 1 is a printed circuit board for a connection arrangement according to the invention;

FIGS. 2a-2b are sectional views of a connection arrangement according to the invention; and

FIGS. 3a-3c are board bodies of printed circuit boards for connection arrangements according to the invention.

### DETAILED DESCRIPTION

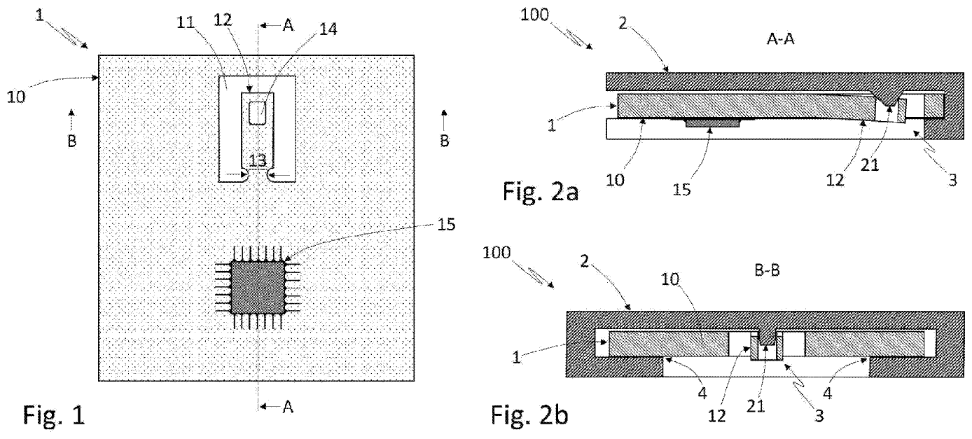

FIG. 1 shows a top view of a printed circuit board 1 for a connection arrangement according to the invention. The printed circuit board 1 comprises the board body 10, on which a microcontroller 15 is arranged, representing an electronic circuit. The board body 10 has the spring tongue 12 that is surrounded by the recess 11 and is provided to form the snap-fit connection according to the invention with the latching nose of a corresponding housing. In the region of its free end, the spring tongue 12 has the receiving opening 14 for receiving the latching nose. In the base portion of the spring tongue 12, which adjoins the rest of the board body 10, the necked portion 13 is formed as a local reduction in the width of the spring tongue 12. When the spring tongue 12 is elastically deflected out of the plane of the board body 10, the bending stress induced in the spring tongue is maximized, i.e., locally concentrated, in the region of the necked portion 13. As a result, the adjacent section of the board body 10 is subjected only to a minor stress load.

FIG. 2a and FIG. 2b show sectional views through a connection arrangement 100 according to the invention, comprising a printed circuit board 1 according to the exemplary embodiment of FIG. 1, wherein the two corresponding section lines AA and BB are also shown in FIG. 1. The connection arrangement 100 further comprises the housing 2, which encloses the board body 10 here by way of example along one complete flat side and with collars surrounding it on three edge sides.

The spring tongue 12 is latched to the latching nose 21 on the housing 2, forming the snap-fit connection 3. The spring tongue 12 is deflected out of the plane of the board body 10 and elastically biased, wherein the latching nose 21 extends into the receiving opening (14) at the free end of the spring tongue 12. Due to the elastic tension of the latched spring tongue 12, a pressing effect is created, which leads to the formation of the frictional connections 4 between the bearing portions of the board body 10 and the housing 2. This increases the static friction between the board body 10 and the housing 2 in such a way that operational vibrations or impacts do not lead to a relative movement between the board body 10 and the housing 2 during practical operation of the connection arrangement, and therefore no unwanted rattling noises are generated.

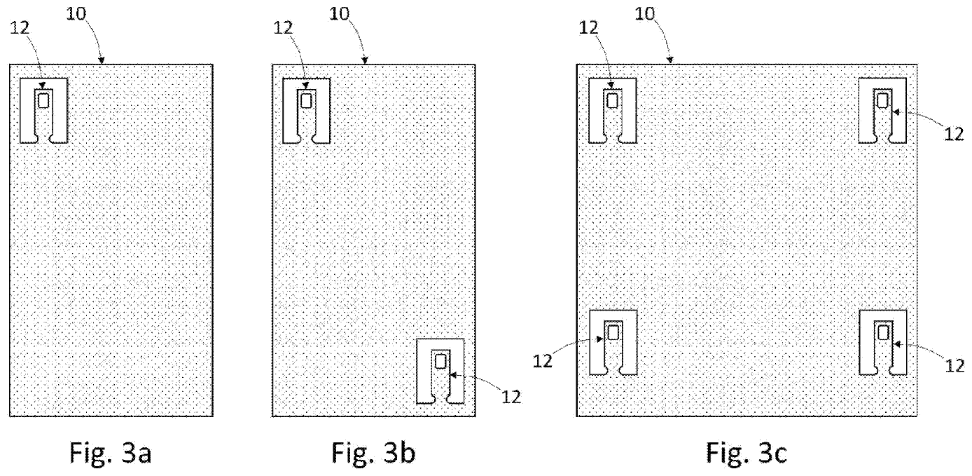

FIG. 3a, FIG. 3b, and FIG. 3c show top views of differently configured board bodies 10 of printed circuit boards for connection arrangements according to the invention. These differ in the number and arrangement of the spring tongues 12 for forming snap-fit connections with the latching noses of correspondingly designed housings.

### LIST OF REFERENCE SYMBOLS

1 printed circuit board
10 board body
11 recess
12 spring tongue
13 necked portion
14 receiving opening
15 microcontroller
2 housing
21 latching nose
3 snap-fit connection
4 frictional connection
100 Connection Arrangement

The above description is that of current embodiments of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. A connection arrangement comprising:
a printed circuit board including a board body; and
a housing, wherein the board body is at least partially enclosed by the housing, and wherein the board body includes at least one spring tongue defined by a recess, the spring tongue being latched to a latching nose of the housing to form a snap-fit connection.

2. The connection arrangement of claim 1, wherein the spring tongue, when latched, is elastically biased such that a frictional connection is formed between bearing portions of the board body and the housing.

3. The connection arrangement of claim 1, wherein the spring tongue includes a base portion adjoining a remaining portion of the board body, the base portion including a necked portion such that bending stress of the spring tongue is maximized at the necked portion when the spring tongue is latched.

4. The connection arrangement of claim 1, wherein the spring tongue includes a receiving opening configured to receive the latching nose.

5. The connection arrangement of claim 1, wherein at least one of the recess or the receiving opening is formed in the board body by milling.
